(19) United States
(12) Patent Application Publication
(10) Pub. No.: US 2015/0041931 A1
(43) Pub. Date: Feb. 12, 2015

(54) Embedded Micro Valve In Microphone

(71) Applicant: Knowles Electronics, LLC, Itasca, IL (US)

(72) Inventors: John Szczech, Schaumburg, IL (US); Sung Bok Lee, Chicago, IL (US); John J. Albers, Chicago, IL (US); Vivian Gill, Chicago, IL (US); Brandon Harrington, Chicago, IL (US); Kurt Friel, Sycamore, IL (US)

(21) Appl. No.: 14/454,337

(22) Filed: Aug. 7, 2014

Related U.S. Application Data
(60) Provisional application No. 61/864,829, filed on Aug. 12, 2013.

(51) Int. Cl. B81B 7/00; B81B 3/00

(52) U.S. Cl. CPC B81B 7/0041; B81B 7/0061; B81B 3/0021; B81B 2201/0257
USPC 257/416

(57) ABSTRACT

A microelectromechanical system (MEMS) apparatus includes a base. A MEMS device is disposed on the base. A cover encloses the MEMS device on the base. A port extends through the base, and the MEMS device is disposed over the port. A diaphragm is embedded within the base and has at least some portions that extend across the port. In an open position, the diaphragm allows the passage of sound energy from the exterior of the apparatus to the interior of the apparatus. In a closed position, the diaphragm makes contact with an outer surface of the port to at least partially block the passage of sound energy from the exterior of the apparatus to the interior of the apparatus.

### CROSS REFERENCE TO RELATED APPLICATION

This patent claims benefit under 35 U.S.C. § 119 (e) to United States Provisional Application No. 61864829 entitled “Embedded Micro valve in Microphone” filed Aug. 12, 2013, the content of which is incorporated herein by reference in its entirety.

### TECHNICAL FIELD

This application relates to acoustic devices and, more specifically, to protecting these devices from pressure and vacuum transients.

### BACKGROUND OF THE INVENTION

Different types of acoustic devices have been used through the years. One type of device is a microphone. In a microelectromechanical system (MEMS) microphone, a MEMS die includes a diagram and a back plate. The MEMS die is supported by a substrate and enclosed by a housing (e.g., a metal can or cover with walls). A sound inlet or acoustic port may extend through the substrate (for a bottom port device) or through the top of the housing (for a top port device). In any case, sound energy traverses through the port, moves the diaphragm and creates a changing potential of the back plate, which creates an electrical signal. Microphones are deployed in various types of devices such as personal computers or cellular phones.

MEMS microphones are susceptible to diaphragm and back plate damage when the microphone port is subjected to transient variations in pressure or vacuum. In particular, pressures during drop testing can generate pressure impulses on an order of approximately 100-1000 psi. Such high pressures exceed the mechanical strength of typical back plate and diaphragm structures resulting in the catastrophe failures of these devices. Previous attempts at solving this problem have not been successful leading to user dissatisfaction with previous approaches.

### BRIEF DESCRIPTION OF THE DRAWINGS

For a more complete understanding of the disclosure, reference should be made to the following detailed description and accompanying drawings wherein:

FIG. 1 is a perspective view of a MEMS microphone according to various embodiments of the present invention;

FIG. 2A is a cross sectional side view of the MEMS microphone of FIG. 1 along line A-A according to various embodiments of the present invention;

FIG. 2B is a perspective cross sectional view of the MEMS microphone of FIG. 1 and FIG. 2A according to various embodiments of the present invention;

FIG. 3 is a perspective view of a diaphragm layer according to various embodiments of the present invention;

FIG. 4A is a view of a diaphragm layer according to various embodiments of the present invention;

FIG. 4B is a view of a diaphragm layer according to various embodiments of the present invention;

FIG. 4C is a view of a diaphragm layer according to various embodiments of the present invention;

FIG. 5 is a side view of the microphone of FIG. 1, FIG. 2A, and FIG. 2B with the diaphragm blocking the port according to various embodiments of the present invention;

FIG. 6 is a side view of the microphone of FIG. 1, FIG. 2A, and FIG. 2B with the diaphragm blocking the port according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Approaches are provided that protect microphones from pressure or vacuum differentials (transients) that occur between the interior of the microphone and the exterior of the microphone. The approaches provided are scalable and cost effective to implement, and are effective at negating the potential consequences of pressure transients in MEMS devices. In one example, pressure or vacuum transients of approximately 760 to 25 Torr will cause the embedded diaphragm to seal the port of the microphone and thereby prevent damage from occurring to the microphone as a result of a pressure or vacuum transient.

In one aspect, the approaches provided herein utilize a diaphragm (e.g., a metal or polymer sheet) which is approximately 0.5 mil (or thinner) and that is embedded within printed circuit board (PCB) layers of the substrate or base of the microphone. This configuration forms a diaphragm, with passage(s) along the perimeter, in the direct sound path of the acoustic port. This embedded diaphragm is, in fact, a second diaphragm that is deployed in addition to the diaphragm associated with a MEMS device (that is internal to the microphone and associated with the MEMS device of the microphone).

The embedded diaphragm is either tensioned or simply supported such that when it deflects in the presence of a pressure pulse or vacuum pulse (e.g., 100 to 1000 psi or 760 to 25 Torr, respectively), it makes contact with the outer surface of the acoustic port, thereby intermittently blocking flow through an acoustic port of the microphone (that under normal conditions would allow sound to enter from the exterior of the microphone to the interior of the microphone). One advantage of the present approaches is that they provide protection against both pressure and vacuum transients. Pressure and/or vacuum transients can result in MEMS back plate and diaphragm damage.

The embedded valve microphone has opening so that when a pressure transient does not occur, sound energy can move from the exterior of the microphone to the interior of the microphone. In one example, the embedded diaphragm has an opening that is generally a “C” shaped with one support provided. In yet another example, three openings and three supports are provided. Other types and shapes of openings may be provided in the embedded diaphragm.

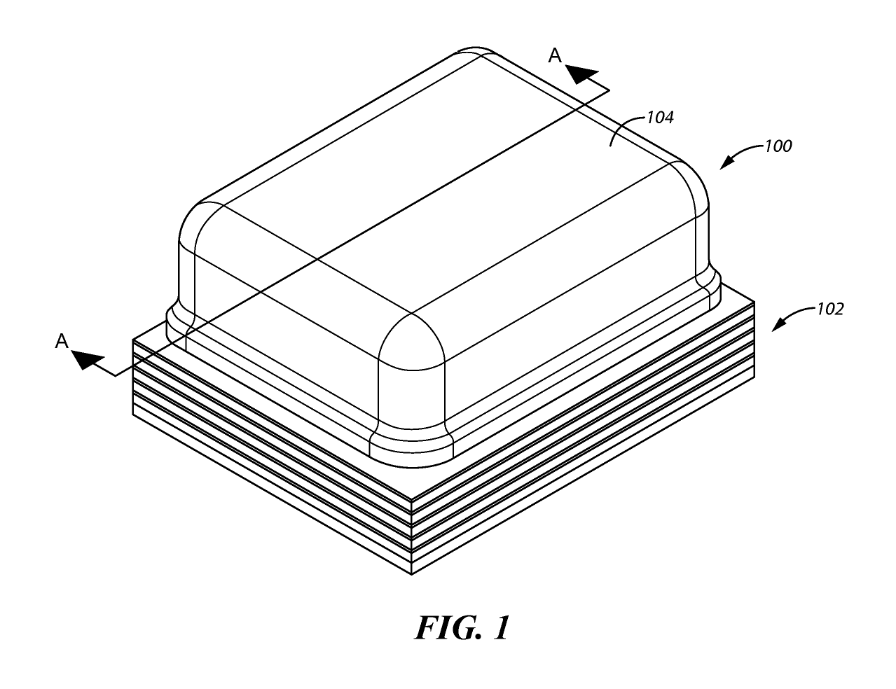

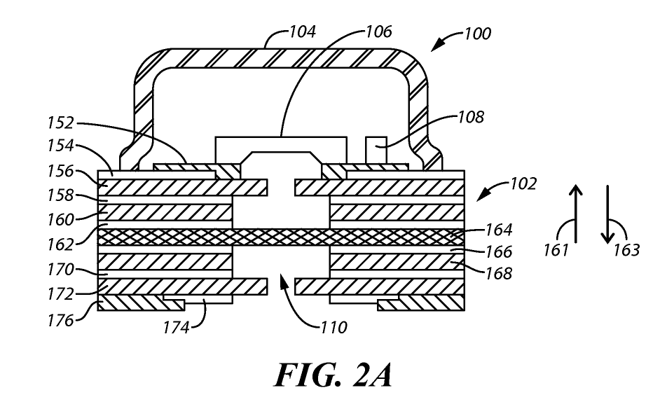

Referring now to FIG. 1, FIG. 2A, and FIG. 2B, a microelectromechanical system (MEMS) microphone includes a base 102, a cover 104, a MEMS device 106 (including a back plate and a diaphragm), an integrated circuit 108, and a opening or port 110 that extends through the base 102.

The base 102 is constructed of multiple layers of materials that form a printed circuit board (PCB). A first passivation layer 152 is disposed on the top of the base 102. A metal layer 154 is disposed under the layer 152. A first core 156, a first adhesive layer 158, a second core 160, a second adhesive layer 162, an embedded micro valve diaphragm 164 that is constructed of polyimide for example, a third adhesive layer 166, a third core 168, a fourth adhesive layer 170, a fourth core 172, a second metal layer 174, and a second passivation layer 176 form the substrate 102. It will be appreciated that this is one possible substrate configuration and that other configurations are possible. In other words, the number and types of layers may vary as long as one of the layers is an embedded micro valve diaphragm layer.

The first passivation layer 152 and the second passivation layer 176 are constructed of a material such as solder resist or other suitable polymer. The purpose of the first passivation layer 152 and the second passivation layer 176 are to protect against oxidation and to prevent solder bridging.

The metal layer 154 and the second metal layer 174 may be constructed of a metal such as ENIG plated copper. The purpose of the first metal layer 154 and the second metal layer 174 are to provide electrical pathways that are wire bondable and solderable.

The first core 156, second core 160, third core 168, and fourth core 172 are constructed of FR-4 material, although other materials such as BT epoxy or flexible polyimide may also be used. The purpose of the first core 156, second core 160, third core 168, and fourth core 172 are to electrically insulate metal layers and to provide structural support to the finished PCB.

The first adhesive layer 158, second adhesive layer 162, third adhesive layer 166, and fourth adhesive layer 170 are constructed of low flow thermoset resin or B-stage epoxy. The purpose of the first adhesive layer 158, second adhesive layer 162, third adhesive layer 166, and fourth adhesive layer 170 is to secure adjacent layers of the base 102 together.

In one aspect, the embedded micro valve diaphragm 164 is constructed of a thin metal or semi-rigid polymer sheet which is approximately 0.5 mil (or thinner), for example. Other dimensions and materials may also be used. The diaphragm 164 deflects upward in the direction of the arrow labeled 161 when the interior pressure is greater than the exterior pressure (the pressure transient) exceeds a predetermined value. The diaphragm 164 will deflect downward in the direction indicated by the arrow labeled 163 when the interior pressure is greater than the exterior pressure (the pressure transient) by a predetermined threshold. In either deflection, the diaphragm 164 blocks air flow through the port 110 from the exterior to the interior or from the interior to the exterior of the microphone. Pressure differentials of a predetermined value cause the diaphragm 164 to move (upward or downward depending upon the direction of the differential). When this pressure differential does not exist, then the diaphragm 164 no longer blocks the port 110 and sound reaches the MEMS device 106.

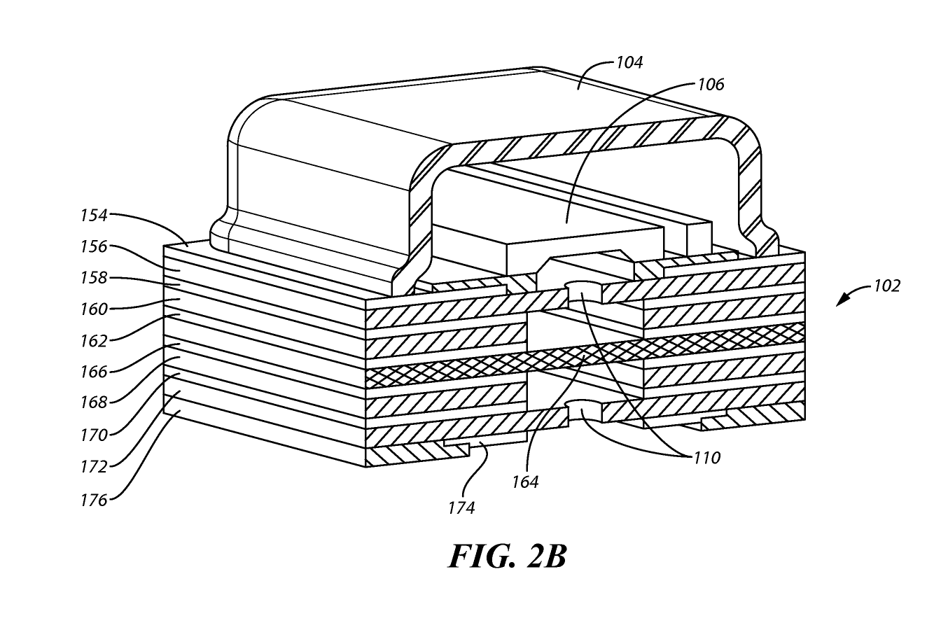

Referring now to FIG. 3, the diaphragm 164 includes an opening 172 and a center portion 171. Sound normally flows through the opening 172 from the exterior of the microphone 100 to the MEMS device 106. However, when the pressure differential exceeds a predetermined value, the center portion 171 moves upward or downward (depending upon the direction of the differential) to acoustically seal the port 110 by plugging the port 110.

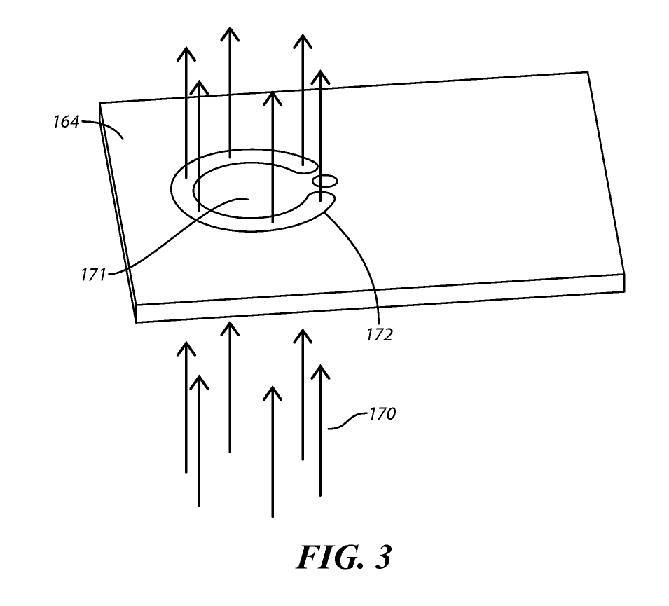

Referring now to FIGS. 4A, 4B, and 4C it can be seen that the configuration of the diaphragm can vary. In one aspect and as shown in these figures, the configuration of the openings in the diaphragm that allow sound to enter the microphone can vary.

In FIG. 4A, the opening in the diaphragm 164 is a “C” shaped opening 165 and includes a support portion 167. In FIG. 4B, the opening in the diaphragm 164 is a “C” shaped opening 165 and is simply supported. In FIG. 4C, the opening in the diaphragm includes multiple openings 169. It will be appreciated that these configurations are examples only and that other configurations are possible. In all examples, when the pressure differential exceeds a predetermined value, the center portion 171 of the diaphragm 164 moves upward or downward (depending upon the direction of the differential) to acoustically seal the port 110 by plugging the port 110.

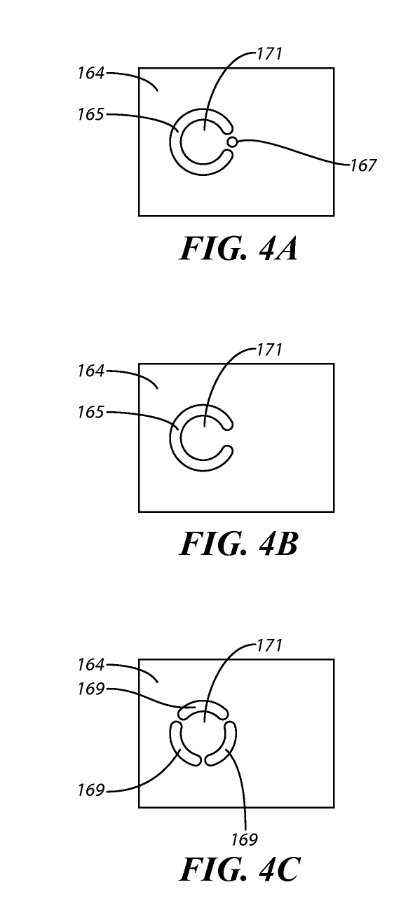

Referring now to FIG. 5, the apparatus 100 is shown where the exterior pressure exceeds the interior pressure by a threshold value (a pressure transient occurs or exists). In this case, the plugging portion 171 (center portion) of the diaphragm 164 bends upward in the direction indicated by the arrow labeled 161 thereby sealing or plugging the opening 192 in layer 156 thereby acoustically sealing the port 110.

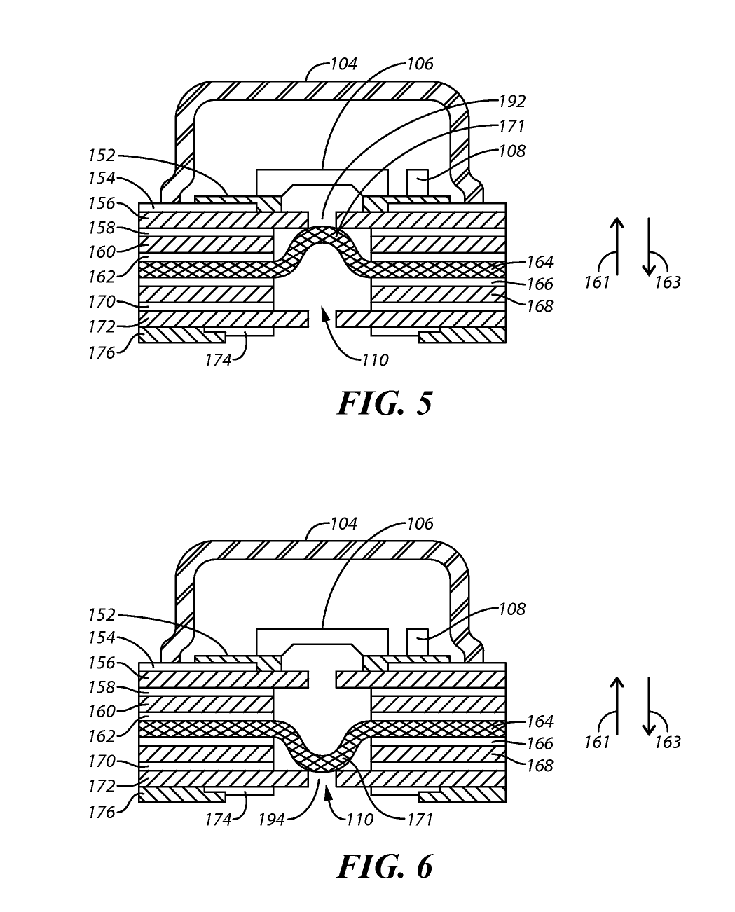

Referring now to FIG. 6, the apparatus 100 is shown where the interior pressure exceeds the interior pressure by a threshold value. In this case, the plugging portion 171 (center portion) of the diaphragm 164 bends downward in the direction of the arrow labeled 163 thereby sealing or plugging the opening 194 in layer 172 thereby acoustically sealing the port 110.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A microelectromechanical system (MEMS) apparatus, the apparatus comprising:
a base;
a MEMS device disposed on the base;
a cover, the cover enclosing the MEMS device on the base;
a port extending through the base, the MEMS device disposed over the port;
wherein a diaphragm is embedded within the base and has at least some portions that extend across the port, such that in an open position the diaphragm allows the passage of sound energy from the exterior of the apparatus to the interior of the apparatus, and such that in a closed position, the diaphragm makes contact with an outer surface of the port to at least partially block the passage of sound energy from the exterior of the apparatus to the interior of the apparatus.

2. The MEMS apparatus of claim 1, wherein the base comprises a printed circuit board.

3. The MEMS apparatus of claim 2, wherein the printed circuit board comprises a plurality of layers and wherein the diaphragm is embedded within the plurality of layers.

4. The MEMS apparatus of claim 3, wherein the plurality of layers are flexible or rigid layers selected from the group consisting of: a passivation layer; a metal layer; an adhesive layer; and a core.

5. The MEMS apparatus of claim 1, wherein the diaphragm comprises one or both of a metal sheet or a polymer sheet.

6. The MEMS apparatus of claim 1, wherein the diaphragm comprises an opening.

7. The MEMS apparatus of claim 1, wherein the opening is a C-shaped opening.

8. The MEMS apparatus of claim 1, wherein the diaphragm comprises multiple openings.

9. A microelectromechanical system (MEMS) apparatus, the apparatus comprising:
a base;
a MEMS device disposed on the base;
a cover, the cover enclosing the MEMS device on the base;
a port extending through the base, the MEMS device disposed over the port;
wherein a diaphragm is embedded within the base and has at least some portions that extend across the port, such that in the presence of pressure differentials between the interior of the apparatus and the exterior of the apparatus, the diaphragm intermittently opens and closes to protect the MEMS device from pressure and vacuum transients.

10. The MEMS apparatus of claim 9, wherein the base comprises a printed circuit board.

11. The MEMS apparatus of claim 10, wherein the printed circuit board comprises a plurality of layers and wherein the diaphragm is embedded within the plurality of layers.

12. The MEMS apparatus of claim 11, wherein the plurality of layers are flexible or rigid layers selected from the group consisting of: a passivation layer; a metal layer; an adhesive layer; and a core.

13. The MEMS apparatus of claim 9, wherein the diaphragm comprises one or both of a metal sheet or a polymer sheet.

14. The MEMS apparatus of claim 9, wherein the diaphragm comprises an opening.

15. The MEMS apparatus of claim 9, wherein the opening is a C-shaped opening.

16. The MEMS apparatus of claim 9, wherein the diaphragm comprises multiple openings.
